(19) United States
(12) Patent Application Publication
(10) Pub. No.: US 2026/0371961 A1
(43) Pub. Date: Nov. 19, 2026

(54) Channeling Implant to Reduce Lateral Dopant Straggling in Transistor Edge Termination

(71) Applicant: Applied Materials, Inc., Santa Clara, CA (US)

(72) Inventors: Qintao Zhang, Mt Kisco, NY (US); Sipeng Gu, Lexington, MA (US)

(73) Assignee: Applied Materials, Inc., Santa Clara, CA (US)

(21) Appl. No.: 19/206,488

(22) Filed: May 13, 2025

(51) Int. Cl. H10P 30/20; H01J 37/09; H01J 37/317; H10D 62/00

(52) U.S. Cl. CPC H10P 30/222; H01J 37/09; H01J 37/3171; H10D 62/054; H01J 2237/0453

(57) ABSTRACT

Disclosed are approaches for forming a transistor edge termination using a channeling implant to reduce lateral dopant straggling. One approach includes patterning a plurality of openings through a masking layer, wherein the masking layer is formed over a substrate in an edge termination region of a semiconductor device. The method may further include forming a plurality of termination regions in the substrate by performing a channeling implant on the semiconductor device, wherein the channeling implant comprises directing ions through the plurality of openings.

### FIELD OF THE DISCLOSURE

The present disclosure relates to semiconductor devices and, more particularly, to methods of forming a transistor edge termination using a channeling implant to reduce lateral dopant straggling.

### BACKGROUND OF THE DISCLOSURE

Semiconductor devices are used to carry large currents and support high voltages. Some semiconductor devices may include Metal Oxide Semiconductor Field Effect Transistors (MOSFET), bipolar junction transistors (BJT), Insulated Gate Bipolar Transistors (IGBT), Junction Barrier Schottky diodes, Gate Turn-Off Transistors (GTO), MOS-controlled thyristors, and various other devices. These semiconductor devices may be fabricated from wide band-gap semiconductor materials, such as silicon carbide (SiC) or gallium nitride (GaN) based semiconductor materials.

Conventional power semiconductor devices may include a semiconductor substrate, such as a SiC substrate, having a first conductivity type (e.g., an n-type substrate) on which an epitaxial layer structure having the first conductivity type (e.g., n-type) is formed. A portion of this epitaxial layer structure, which may comprise one or more separate layers, functions as a drift region of the semiconductor device. The device typically includes an “active region,” which includes one or more power semiconductor devices that have a junction, such as a p-n junction or a Schottky junction. The active region may be formed on and/or in the drift region. The active region acts as a main junction for blocking voltage in the reverse bias direction and providing current flow in the forward bias direction.

The semiconductor device may also have an edge termination in a termination region that is adjacent the active region. The edge termination occupies a relatively large portion of SiC MOSFET dies, and often includes isolated P-type islands or regions. Edge terminations come with certain limitations, however. For example, edge terminations may include deep shielding patterns (e.g., formed by deep ion implantation) to provide a smooth field between the termination and active area. However, isolated pWell edge termination structures are quite sensitive to space between implanted islands. Forming such patterns using high energy implantation may result in lateral extension (or “straggle”) between adjacent implant regions, which may electrically connect adjacent implant features. As a result, edge termination scaling can't be accomplished for a same operational voltage.

Furthermore, some existing prior art approaches use multiple, sequential mask and implant processes to implement both deep and shallow implantation in the edge termination, while also reducing implantation window width. This multi-masking approach increases processing complexity and cost without adequately addressing dopant straggle.

It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

One approach includes patterning a plurality of openings through a masking layer, wherein the masking layer is formed over a substrate in an edge termination region of a semiconductor device. The method may further include forming a plurality of termination regions in the substrate by performing a channeling implant on the semiconductor device, wherein the channeling implant comprises directing ions through the plurality of openings.

In another approach, a method for forming an edge termination region may include patterning a plurality of openings through a masking layer, wherein the masking layer is formed over a substrate in the edge termination region of a metal-oxide-semiconductor field-effect transistor. The method may further include forming a plurality of termination regions in the substrate by performing a channeling implant on the semiconductor device, wherein the channeling implant comprises directing ions through the plurality of openings.

In yet another approach, an ion implanter may include a plurality of beam line components for performing a channeling implant to a substrate within a processing chamber, wherein channeling implant comprises directing ions through a plurality of openings of a masking layer formed over the substrate in an edge termination region of a metal-oxide-semiconductor field-effect transistor, and wherein the channeling implant forms a plurality of termination regions in the substrate.

### BRIEF DESCRIPTION OF THE DRAWINGS

The accompanying drawings illustrate exemplary approaches of the disclosure, including the practical application of the principles thereof, as follows:

FIG. 1 illustrates a side cross-sectional view of a portion of a device, such as a MOSFET, according to embodiments of the present disclosure;

FIG. 2 illustrates a side cross-sectional view of the device following a mask patterning process, according to embodiments of the present disclosure;

FIG. 3 illustrates a side cross-sectional view of the device during a channeling implant, according to embodiments of the present disclosure;

FIG. 4A illustrates a side cross-sectional view of a device following formation of a plurality of termination regions, according to embodiments of the present disclosure;

FIG. 4B is a close-up view of a termination region, according to embodiments of the present disclosure;

FIG. 5 illustrates a schematic diagram of a processing apparatus according to embodiments of the present disclosure; and

FIG. 6 illustrates a diagram of a cluster tool according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, disclosed herein are approaches for forming a transistor edge termination using a channeling implant to reduce lateral dopant straggling in a transistor, such as a SiC MOSFET. Unlike prior approaches that use multiple masks to address high-energy implantation straggling, the current approach uses a single mask together with a channeling ion implant to effectively control straggling and thus increase device scaling. The channeling implant may be performed at a lower energy (e.g., below 5 MeV) to reduce collisions as the ions pass SiC lattice of the device layer(s).

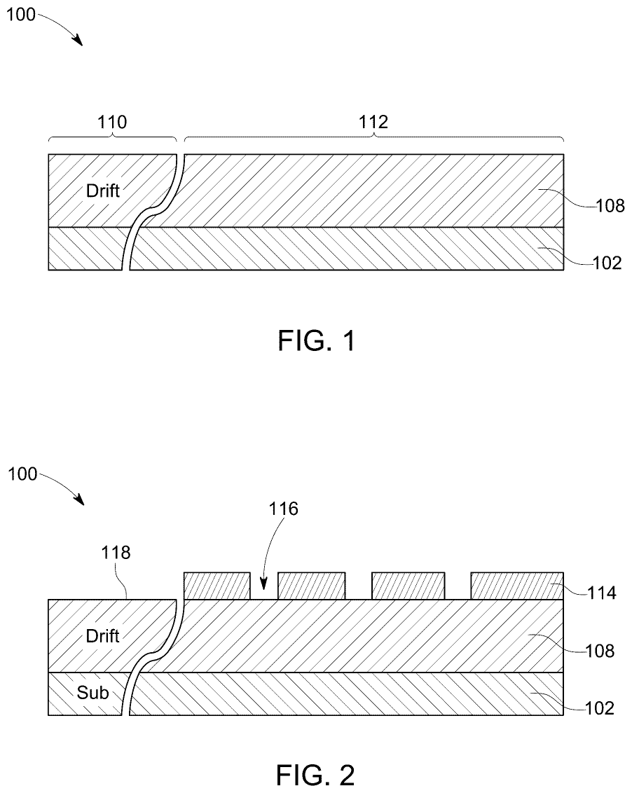

FIG. 1 is a side cross-sectional view of a portion of a semiconductor device (hereinafter “device”) 100, such as a MOSFET, at one stage of processing, according to embodiments of the present disclosure. As shown, the device 100 may include a substrate 102 and a drift layer 108 formed over the substrate 102, wherein the substrate 102 may be a highly doped n+ substrate layer and the drift layer 108 may be a lightly-doped n− SiC drift layer.

The device 100 may include an active region 110 and an edge termination region 112. Although not shown, in some embodiments, a perimeter region may extend between the active region 110 and the edge termination region 112. The edge termination region 112 may help reduce undesired electric field crowding effects that may occur at the edges of the active region 110.

As shown in FIG. 2, a masking layer 114 may then be formed (e.g., deposited) over the drift layer 108, and then patterned (e.g., etched) to form a plurality of openings 116 therein. The plurality of openings 116 may be formed selective to an upper surface 118 of the drift layer 108. Although non-limiting, the masking layer 114 may be hardmask.

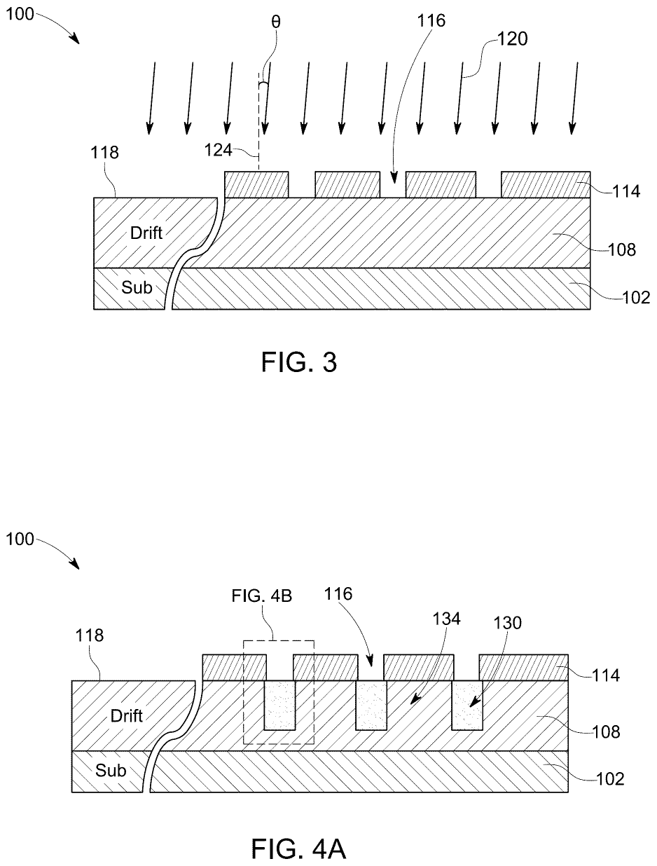

As shown in FIG. 3, a channeling implant 120 may then be performed on the device 100, wherein the channeling implant 120 includes directing ions through the plurality of openings 116. More specifically, the channeling implant 120 includes directing ions into the upper surface 118 of the drift layer 108 at a non-zero angle θ relative to a perpendicular 124 extending from an upper surface 126 of the masking layer 114. In one example, a SiC wafer may have a 4° off-cut to the [0001̅] direction of the crystal for step epitaxial growth. Therefore, the non-zero implant angle θ into the upper surface 118 of the drift layer 108 could enable channeling implantation leading to a deeper doping with a uniform, box-like profile. Although non-limiting, the non-zero angle θ may be between 1-10°. To achieve the desired non-zero angle relative to the perpendicular 124, a wafer support (not shown) supporting the device 100 and/or a tool (not shown) providing the ions of the channeling implant 120 may be oriented or angled relative to one another.

The channeling implant 120 also reduces implantation damage and straggling due to the lower doping energy and less implant steps. For example, the implant energy of the channeling implant 120 may be less than 5 MeV in some non-limiting embodiments. In various embodiments, the channeling implant 120 may include directing at least one of the following ion species into the exposed upper surface 118 of the drift layer 108: aluminum, nitrogen, phosphorous, carbon, silicon, arsenic, antimony, and boron. Furthermore, the ion species may be delivered in one or more sequential implant steps.

As used herein, the ions of the channeling implant 120 may be delivered as an ion beam, which can take any form, such as a pencil or spot beam, a ribbon beam, a scanned beam, or any other form in which ions are directed toward the device 100, and all such forms are contemplated as falling within the scope of the disclosure.

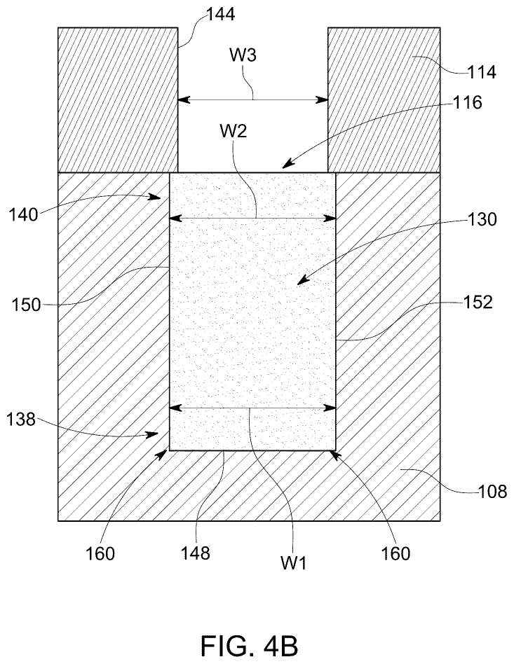

The channeling implant 120 results in a plurality of termination regions 130 being formed in the drift layer 108, as shown in FIG. 4A. Each of the termination regions 130 may be formed beneath a corresponding opening 116 through the masking layer 114. The termination regions 130 may be doped shielding areas separated from one another by areas 134 of the drift layer 108. As better shown in FIG. 4B, each termination region 130 is generally characterized by a uniform rectangular, or box-like, profile having a first dimension (W1) along a lower portion 138 that is substantially the same as a second dimension (W2) along an upper portion 140. Said differently, a lateral width of the of the termination regions 130 is substantially constant along an entire depth thereof, and the width does not significantly extend beyond a downward projection of an edge 144 defining the opening 116. That is, W1 and W2 may be substantially the same as a third dimension (W3), which is defined by a distance across the opening 116. In other embodiments, W3 is up to 20% less than W1 and/or W2.

The termination region 130 may be further characterized by a relatively flat bottom edge 148 and parallel side edges 150, 152 that meet at corners 160. In the embodiment shown, the bottom edge 148 of the termination region 130 extends only partially through a depth of the drift layer 108. That is, the termination region 130 does not extend to an upper surface of the substrate 102. The termination regions 130 offer greater isolation, less leakage, and lower breakdown voltage, thus reducing the likelihood of device failure while also allowing for continued device scaling. Advantageously, the termination regions 130 may be formed with the use of a single mask, i.e., masking layer 114.

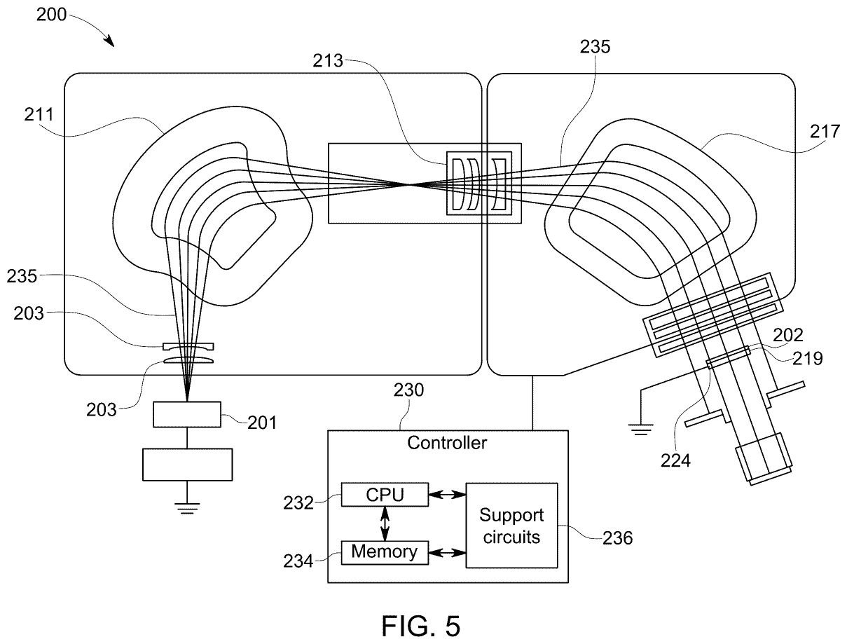

FIG. 5 illustrates a schematic diagram of a processing apparatus 200 useful to perform processes described herein. The processing apparatus 200 may include an ion source 201 for generating ions. For example, the ion source 201 may provide an ion beam treatment, such as the channeling implant 120 demonstrated in FIG. 3.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. In some embodiments, the platen 219 may be heated using an external or embedded heating element 224, such as a resistive heater, or may be heated using radiant heat, such as heating lamps disposed above or below the platen 219. In other embodiments, the heating element may additionally, or alternatively, be located in a load lock chamber or a separate pre-heat chamber to pre-heat the wafer 202 before it reaches the platen 219. Even with a pre-heat, the platen 219 may include the internal heating element 224. The substrate 202 may be the same as the substrate 102 described above. The substrate 202 may be moved in one or more dimensions (e.g. translate, rotate, tilt, etc.) by a component sometimes referred to as a rotating platen or “roplat” (not shown). It is also contemplated that the processing apparatus 200 may be configured to perform heated treatment processes to provide for improved control of treatment characteristics, such as the ion trajectory and ion treatment energy utilized to treat the substrate 202.

In operation, ions of the desired species, for example, dopant ions, are generated and extracted from the ion source 201. Thereafter, the extracted ions 235 travel in a beam-like state along the beam-line components and may be directed to be incident on the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to process with desired ions while reducing the probability of undesirable ions (impurities) being incident on the substrate 202.

In some embodiments, the processing apparatus 200 can be controlled by a processor-based system controller such as controller 230. For example, the controller 230 may be configured to control beam-line components and processing parameters associated with beam-line ion treatments. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Ion processing and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

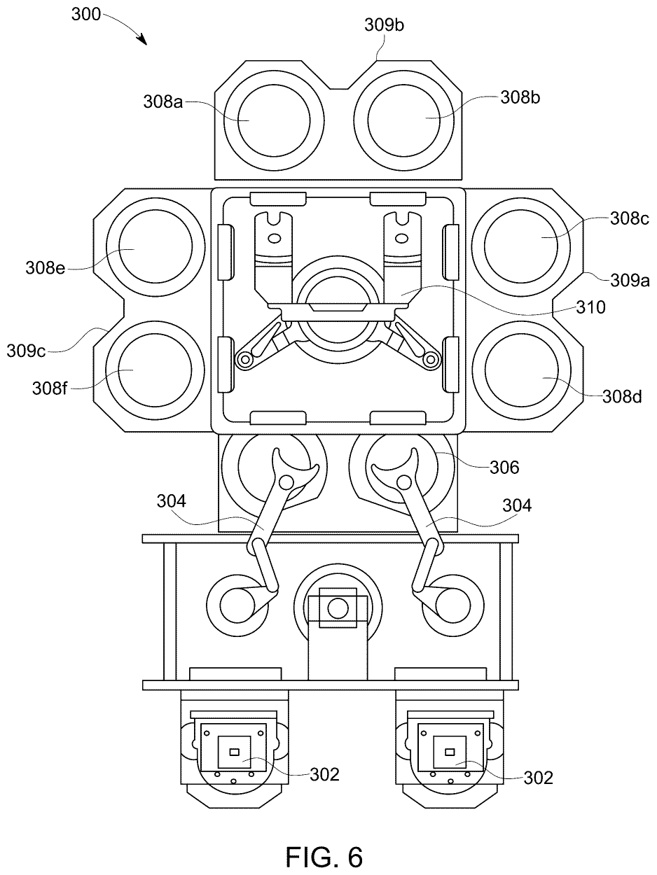

FIG. 6 illustrates a top plan view of one embodiment of another processing system 300 including a plurality of chambers according to some embodiments. As shown, a pair of front opening unified pods 302 supply substrates of a variety of sizes that are received by robotic arms 304 and placed into a low-pressure holding area 306 before being placed into one of the substrate processing chambers 308a-f, positioned in tandem sections 309a-c. A second robotic arm 310 may be used to transport the substrate wafers from the holding area 306 to the substrate processing chambers 308a-f and back.

The substrate processing chambers 308a-f may include one or more system components for depositing, treating, growing, annealing, curing, implanting, and/or etching the substrate and/or a material layer on the substrate or wafer. In one configuration, one or more of the processing chambers, for example 308a, may be used to implant the substrate and/or the material layers formed atop the substrate using a ion treatment from processing apparatus 200, which may be present within the processing chamber 308a.

Any one or more of the processes described may be carried out in additional chambers separated from the fabrication system shown in different embodiments. It will be appreciated that additional configurations of deposition, ion treating, growing, etching, annealing, and curing chambers for substrates and material layers are contemplated by the processing system 300. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed sequentially in multiple chambers while maintaining a particular vacuum environment between discrete processes.

The processing system 300, or more specifically, chambers incorporated into the processing system 300 or other processing systems, may be used to produce structures according to some embodiments of the present disclosure.

In sum, embodiments herein provide a channeling implant in which one or more dopants may be implanted at a first implantation angle at which a channeling effect may occur in the SiC substrate to produce uniform, boxlike dopant termination regions. Channeling implants can significantly increase the range of implanted dopants and can significantly reduce the fraction of ions that are reflected within the drift layer. A larger fraction of the ions can be implanted along the target direction. Furthermore, possible out-diffusion of implanted dopants during subsequent high temperature steps can be suppressed or can even be substantially avoided.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
patterning a plurality of openings through a masking layer, wherein the masking layer is formed over a substrate in an edge termination region of a semiconductor device; and
forming a plurality of termination regions in the substrate by performing a channeling implant to the semiconductor device, wherein the channeling implant comprises directing ions through the plurality of openings.

2. The method of claim 1, wherein forming the plurality of termination regions comprises forming each termination region of the plurality of termination regions beneath a corresponding opening of the plurality of openings.

3. The method of claim 1, wherein the channeling implant comprises directing ions into a drift layer formed over the substrate.

4. The method of claim 3, wherein the drift layer is a lightly-doped semiconductor drift layer.

5. The method of claim 3, wherein the channeling implant comprises directing ions at a non-zero angle relative to a perpendicular extending from an upper surface of the masking layer.

6. The method of claim 3, wherein the channeling implant comprises directing at least one of the following ion species into an exposed upper surface of the drift layer: aluminum, nitrogen, phosphorous, carbon, silicon, arsenic, antimony, and boron.

7. The method of claim 1, wherein the channeling implant is performed at an implant energy below 5 MeV.

8. A method for forming an edge termination region, the method comprising:
patterning a plurality of openings through a masking layer, wherein the masking layer is formed over a drift layer in the edge termination region of a metal-oxide-semiconductor field-effect transistor; and
forming a plurality of termination regions in the drift layer by performing a channeling implant to the metal-oxide-semiconductor field-effect transistor, wherein the channeling implant comprises directing ions through the plurality of openings.

9. The method of claim 8, wherein forming the plurality of termination regions comprises forming each termination region of the plurality of termination regions beneath a corresponding opening of the plurality of openings.

10. The method of claim 8, wherein the channeling implant comprises directing ions into the drift layer at a non-zero angle relative to a perpendicular extending from an upper surface of the masking layer.

11. The method of claim 8, wherein the channeling implant comprises directing at least one of the following ion species into an exposed upper surface of the drift layer: aluminum, nitrogen, phosphorous, carbon, silicon, arsenic, antimony, and boron.

12. The method of claim 8, wherein the drift layer is a lightly-doped semiconductor drift layer formed over a substrate.

13. The method of claim 8, wherein the channeling implant is performed at an implant energy below 5 MeV.

14. An ion implanter, comprising:
a plurality of beam line components for performing a channeling implant to a metal-oxide-semiconductor field-effect transistor within a processing chamber, wherein the channeling implant comprises directing ions through a plurality of openings of a masking layer formed over a drift layer in an edge termination region of the metal-oxide-semiconductor field-effect transistor, and wherein the channeling implant forms a plurality of termination regions in the drift layer.

15. The ion implanter of claim 14, wherein the plurality of beam line components are operable to form each termination region of the plurality of termination regions beneath a corresponding opening of the plurality of openings.

16. The ion implanter of claim 14, wherein the channeling implant comprises directing ions into the drift layer at a non-zero angle relative to a perpendicular extending from an upper surface of the masking layer.

17. The ion implanter of claim 14, wherein the channeling implant comprises directing at least one of the following ion species into an exposed upper surface of the drift layer: aluminum, nitrogen, phosphorous, carbon, silicon, arsenic, antimony, and boron.

18. The ion implanter of claim 14, wherein the drift layer is formed over a substrate.

19. The ion implanter of claim 14, wherein the channeling implant is performed at an implant energy below 5 MeV.

20. The ion implanter of claim 14, wherein each termination region of the plurality of termination regions has a rectangular shaped profile.
